(19) United States
(12) Patent Application Publication
(10) Pub. No.: US 2024/0292580 A1
(43) Pub. Date: Aug. 29, 2024

(54) DISPLAY ASSEMBLY WITH LOOPBACK COOLING

(71) Applicant: Manufacturing Resources International, Inc., Alpharetta, GA (US)

(72) Inventor: William Dunn, Alpharetta, GA (US)

(21) Appl. No.: 18/657,967

(22) Filed: May 8, 2024

Related U.S. Application Data
(63) Continuation of application No. 18/112,976, filed on Feb. 22, 2023, now Pat. No. 12,010,824.
Application No. 18/112,976 is a continuation of application No. 17/372,623, filed on Jul. 12, 2021, now Pat. No. 11,617,287.
Application No. 17/372,623 is a continuation of application No. 16/798,909, filed on Feb. 24, 2020, now Pat. No. 11,096,317.
(60) Provisional application No. 62/810,839, filed on Feb. 26, 2019.

(51) Int. Cl. H05K 7/20; G02F 1/1333

(52) U.S. Cl. CPC H05K 7/20972; G02F 1/133385

(57) ABSTRACT

A display assembly with cooling pathways includes a housing for an electronic display and a closed, continuous airflow pathway. Partition(s) located within the housing partially separate an equipment storage area for electronic equipment from the continuous airflow pathway. The partition(s) define, at least in part, a sub-pathway within, but separated from, the closed, continuous airflow pathway. Fan(s), when activated, cause a portion of a flow of circulating gas traveling through the closed, continuous airflow pathway to leave the same and instead travel through the sub-pathway pathway while a remainder of the flow continues through the closed, continuous airflow pathway, before rejoining the closed, continuous airflow pathway.

### CROSS-REFERENCE TO RELATED APPLICATIONS

This application is a continuation of U.S. patent application Ser. No. 18/112,976 filed Feb. 22, 2023, which is a continuation of U.S. patent application Ser. No. 17/372,623 filed Jul. 12, 2021, now U.S. Pat. No. 11,617,287 issued Mar. 28, 2023, which is a continuation of U.S. patent application Ser. No. 16/798,909 filed Feb. 24, 2020, now U.S. Pat. No. 11,096,317 issued Aug. 17, 2021, which claims the benefit of U.S. provisional patent application Ser. No. 62/810,839 filed Feb. 26, 2019, the disclosure of each of which are hereby incorporated by reference as if fully restated herein.

### TECHNICAL FIELD

Exemplary embodiments relate generally to systems and methods for thermally managing display assemblies, and components thereof, by providing loopback cooling.

### BACKGROUND AND SUMMARY OF THE INVENTION

Electronic displays are increasingly being used in various out of home applications, such as on sidewalks, bus shelters, walls, and the like to provide information, wayfinding, and communication services, display advertisements, and the like. These electronic displays and their related components and equipment are often subject to extreme temperatures, sunlight, wind, rain, hail, sleet, snow, floods, vandalism, and the like. To help protect the sensitive electronic displays as well as the related sensitive components and equipment, in many cases the electronic display(s) and the related components and equipment are placed within a ruggedized housing. However, the electronic displays and their related components and equipment generally generate heat, which must be removed from the assembly to prevent damage. In many cases, simply allowing ambient air to pass over the exterior of the assembly is insufficient to provide the level of cooling required to keep the assembly functional and operating at optimal levels. Therefore, what is needed is a system and method for thermally managing a display assembly.

Systems and methods for thermally managing display assemblies are provided. Such systems and methods may include loopback cooling, especially for components located at an equipment storage device. Each display assembly may comprise one or more open loop pathways for ambient air and one or more closed loop pathways for circulating gas. The open loop pathway(s) and the closed loop pathway(s) may be configured to provide thermal interaction between the ambient air in the open loop pathway(s) and the circulating gas within the closed loop pathway(s). Such thermal interaction may occur at one or more heat exchangers located within the display assembly. One or more open loop channels may be located behind one or more respective electronic displays. One or more storage areas may be defined by the open loop channel(s), the heat exchanger(s), and one or more barriers. One or more equipment storage devices may be located within each storage area. A fan unit may push or pull circulating gas through front channels, which may be defined between transparent covers and the respective electronic displays, as well as through the heat exchanger(s) such that the one or more closed loop pathways are formed. The area between the heat exchanger(s) and the fan unit may be relatively low pressure compared to the areas between the fan unit and the front channels. This may be due to the pressures created by the fan unit.

A portion of the circulating gas in the closed loop passing through the fan unit may be looped back towards the storage area due to a pressure imbalance. A barrier may extend between the equipment storage devices and the fan unit to separate the loopback flow entering and exiting the storage area. The loopback flow may circulate or enter the equipment storage devices to cool the equipment stored therein before reentering the fan unit and rejoining the circulating gas. In this way, an appropriate amount of the circulating gas which has already been cooled at the heat exchanger may be provided to the equipment in the equipment storage devices. Otherwise, such equipment would likely be exposed only to heated circulating gas exiting the front channels.

Further features and advantages of the systems and methods disclosed herein, as well as the structure and operation of various aspects of the present disclosure, are described in detail below with reference to the accompanying figures.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical or equivalent features, and wherein:

FIG. 1 is a perspective view of an exemplary display assembly also indicating section line A-A; and

FIG. 2 is a top cross-sectional view along section line A-A of FIG. 1.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

Embodiments of the invention are described herein with reference to illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

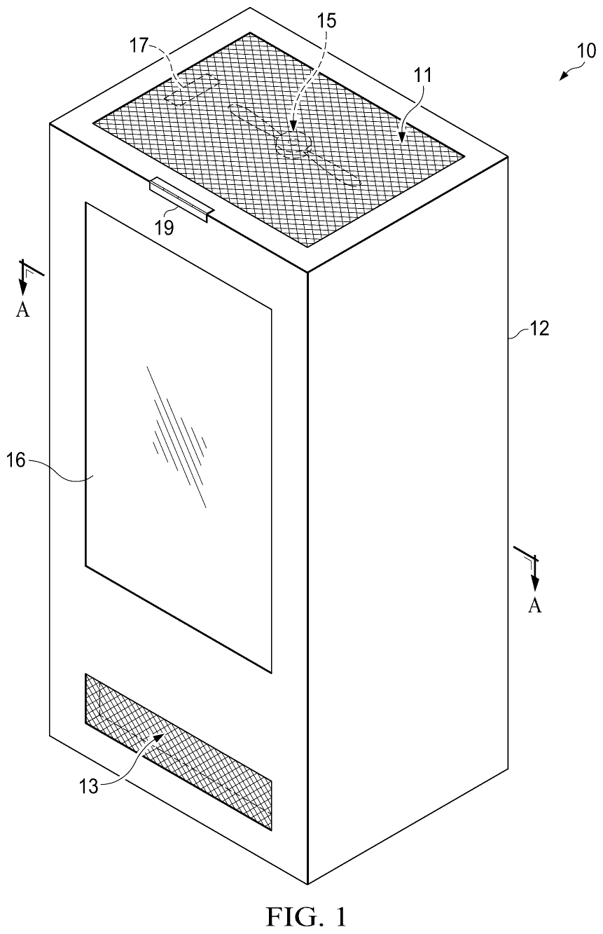

FIG. 1 is a perspective view of an exemplary display assembly 10. The display assembly 10 may comprise a housing 12 for one or more electronic displays 18 and 20. A first and second electronic display 18 and 20, in exemplary embodiments, are placed in a back to back arrangement and located on either side of the housing 12. In other exemplary embodiments, the electronics displays 18 and 20 may be placed above and below or next to one another. Any number of electronic displays 18 and 20 provided in any size, shape, arrangement, orientation, and the like may be utilized. The electronic displays 18 and 20 may be liquid crystal, organic light emitting diode, plasma, rear projection, cathode ray tube type displays, some combination thereof, or the like. One or more of electronic displays 18 and 20 may comprise touch screen components or otherwise be capable of receiving touch input. The electronic displays 18 and 20 may be directly backlit or edge lit. The electronic displays 18 and 20 may comprise a cavity for each respective backlight.

Said electronic displays 18 and 20 may each be placed behind a respective transparent cover 14 and 16. The transparent covers 14 and 16 may be comprised of glass, a polymer, acrylic, some combination thereof, or the like. In exemplary embodiments, each transparent cover 14 and 16 may be formed by two transparent sheets joined by an optically clear adhesive, though such is not required. The housing 12 and the transparent covers 14 and 16 may substantially encase the electronic displays 18 and 20 in some exemplary embodiments.

In exemplary embodiments, one or more sides of the display assembly 10 may comprise a cavity for a static poster instead of, or in addition to, an electronic display 18 and 20. In other exemplary embodiments, a cavity for a static poster may be included in addition to the electronic displays 18 and 20. Such cavities may be back lit or edge lit to illuminate the poster or other signage located therein. In still other exemplary embodiments, instead of an electronic display 18 and 20 or a cavity for a static poster, one or more sides of the display assembly 10 may comprise a blank cover. The blank cover may be comprised of a metallic, a polymer, glass, or the like. For example, without limitation, the blank cover may be comprised of black glass, though any material may be utilized.

The display assembly 10 may further comprise an intake opening 11 and an exhaust opening 13. The intake opening 11 may facilitate the ingestion of ambient air 30. The exhaust opening 13 may facilitate the exhaustion of ambient air 30. The intake opening 11 and/or the exhaust opening 13 may comprise a grid, screen, filter, some combination thereof, or other device to limit or prevent certain debris and particulate from entering the display assembly 10. In exemplary embodiments, the intake opening 11 may be located at or near the top of the display assembly 11 and the exhaust opening 13 may be located at or near the bottom of the display assembly 10. However, any location of the intake opening 11 and the exhaust opening 13 may be utilized. For example, without limitation, the intake opening 11 may be located on or near the upper portion of the display assembly 10, and the exhaust opening 13 may be located on or near the lower portion of the display assembly 10. In still other exemplary embodiments, the intake opening 11 or the exhaust opening 13 may be located near a mid-point of the display assembly 10 or on the left or right side of the display assembly 10.

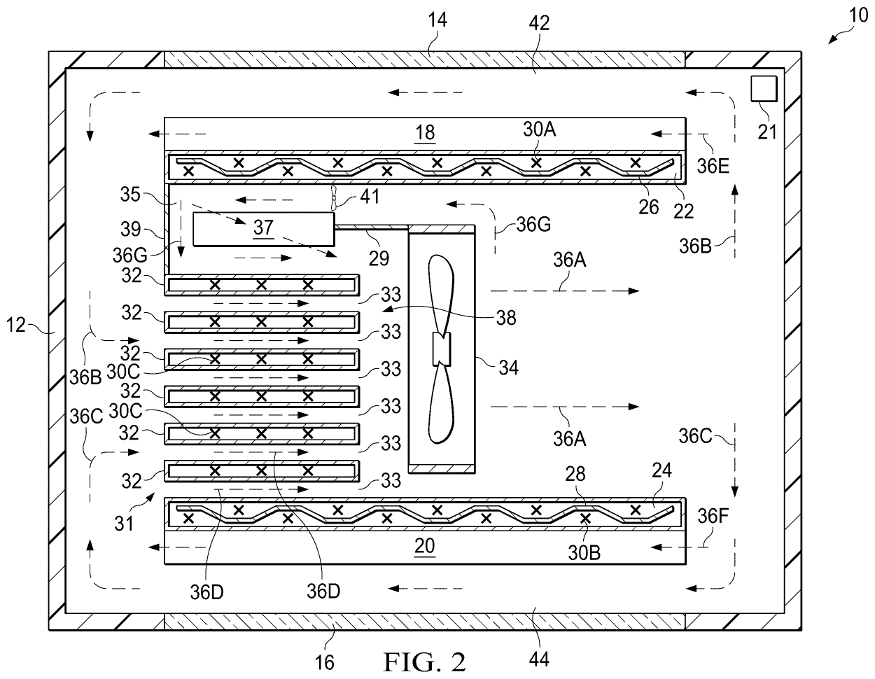

FIG. 2 is a top cross-sectional view of the display assembly 10 of FIG. 1 taken along section line A-A. An open loop channel 22 and 24 may be placed behind each respective electronic display 18 and 20, though other locations may be utilized. Each open loop channel 22 and 24 may be configured to receive a respective portion, or a separate flow, of the ingested ambient air 30A and 30B, which may travel through the respective open loop channel 22 or 24 before exiting the display assembly 10. Each open loop channel 22 and 24 may comprise corrugation 26 and 28. The corrugation 26 and 28 may be provided in any number of layers and in any shape(s). In exemplary embodiments, the open loop channels 22 and 24 may extend along and directly behind the backlight of each respective electronic display 18 and 20, though such is not required. The open loop channels 22 and 24 may comprise entirely separate pathways through the display assembly 10 or may be combined at one or more locations.

One or more open loop fans 15 may be placed on or near the intake opening 11 or the open loop channels 22 and 24 in order to force the ambient air 30A and 30B through the open loop channels 22 and 24. Various temperature, pressure, fan speed, air speed, and other sensors 17 may be placed within or near the open loop channels 22 and 24. Data from said sensors 17 may be received at one or more processors in electronic communication with the open loop fans 15. Operation of the open loop fans 15 may be adjusted to keep the display assembly 10, and various components and equipment thereof, from overheating and/or performing at various levels.

One or more heat exchangers 31 may be located between the first and second electronic displays 18 and 20. In exemplary embodiments, the heat exchanger(s) 31 are located between the first and second open loop channels 22 and 24. The heat exchanger(s) 31 may accept a portion, or flows, of the ingested ambient air 30C. The heat exchanger(s) 31 may comprise one or more layers 32 for ambient air 300. The heat exchanger(s) 31 may comprise one or more layers 33 for circulating gas 36D. In exemplary embodiments, the layers 32 for the ambient air 30C are alternated with layers 33 for the circulating gas 36D, though such is not required. The heat exchanger(s) 31 may be cross flow, counter flow, parallel flow, or other types of heat exchangers.

A fan unit 34 may be placed adjacent to the heat exchanger 31 in order to force the circulating gas 36D to pass through the layers 33 of the heat exchanger 31. The fan unit 34 may be configured to force the circulating gas 36D through some or all of a closed loop pathway within the display assembly 10 when operated. The fan unit 34 may be positioned and/or otherwise configured to create an area of relatively low pressure 38 at a first side of the fan unit 34. The first side may be the side of the fan unit 34 facing the heat exchanger 31. The fan unit 34 may be positioned and/or otherwise configured to create an area of relatively high pressure 38 on a second side of the fan unit 34. The second side of the fan unit 34 may be opposite the first side. The fan unit 34 may comprise one or more fans which may be placed within one or more housings. Where more than one heat exchanger 31 is provided, more than one fan unit 34 may be utilized.

Some or all of the circulating gas 36D may pass through the fan unit 34 and exit as the circulating gas flow 36A. The circulating gas flow 36A may subsequently be divided into circulating gas flows 36B and 36C which may travel through a first and second front channels 42 and 44, respectively. The first front channel 42 may be located in the space between the first transparent cover 14 and the first electronic display 18. The second front channel 44 may be located in the space between the second transparent cover 16 and the second electronic display 20. These circulating gas flows 36B and 36C may be relatively cool after passing through the heat exchanger 31. These circulating gas flows 36B and 36C may pick up heat generated by solar loading as they pass through the front channels 42 and 44. These now relatively warm circulating gas flows 36B and 36C may be returned to the heat exchanger 31 to be cooled by the ambient gas passing through the heat exchanger 31. Various temperature, pressure, fan speed, air speed, and other sensors 21 may be placed along this closed loop pathway and data from said sensors 21 may be received at a processor in electronic communication with the fan unit 34 and operation of the fan unit 34 may be adjusted to keep the display assembly 10, and various components and equipment thereof, from overheating and/or operating at desired levels.

Each of the electronic displays 18 and 20 may include a backlight cavity for the backlight. The backlight cavity may be located behind the display element itself (e.g., liquid crystal layer). A portion of the circulating gas 36E and 36F may, in exemplary embodiments, be bled into these backlight cavities. This portion of the circulating gas 36E and 36F may travel through the respective backlight cavity and rejoin the circulating gas flows 36B and 36C. These backlight cavity flows 36E and 36F may exert pressure against the display elements of the electronic displays 18 and 20 to prevent the electronic displays 18 and 20 from bowing.

One or more barriers 39 may extend from one or more of the open loop channels 22 and 24 to the heat exchanger 31. In this way, a portion of what would otherwise be area for the flow of the circulating gas 36B and 36C may be partitioned. In exemplary embodiments, the barrier(s) 39 extends from the rear surface of the first open loop channel 22 such that each barrier 39 is substantially aligned with a side surface of the open loop channel 22, though such is not required. In this way, the circulating gas 36B or 36C exiting the respective front channels 42 or 44 may be forced to travel a distance before entering the heat exchanger 31. Regardless, the barrier(s) 39 may partition storage area(s) 35. The barrier(s) 39 may comprise any number of components, members, walls, partitions, or the like arranged in any shape to define any size or shape storage area 35.

One or more equipment storage devices 37 may be positioned within each storage area 35. In exemplary embodiments, the equipment storage devices 37 may be located in the storage area 35. The storage area 35 may be defined between the barrier 39, the open loop channels 22 or 24, and the heat exchanger 31 in exemplary embodiments, without limitation. The display assembly 10 may comprise one or more storage areas 35, and one or more corresponding barriers 39, at multiple locations within the display assembly 10. For example, without limitation, a second storage area 35 may be located behind the second open loop channel 24.

The equipment storage device 37 may each comprise one or more server racks, plates, racks, cabinets, compartments, trays, shelves, some combination thereof, or the like. In exemplary embodiments, the equipment storage device 37 comprises a 1U server racks, though such is not required. A number of such equipment storage devices 37 may be provided in a given storage area 35. For example, without limitation, multiple equipment storage devices 37 may be provided vertically through storage area 35 as it extends through the display assembly 10. Different equipment storage devices 37 may be provided in different storage areas 35. Each of the equipment storage devices 37 may be configured to receive one or more pieces of equipment for operating the electronic displays 18 and 20 and the display assembly 10, as well as various customer equipment such as, but not limited to, sensors, network connectivity devices, communications equipment, video players, storage devices, processors, sensors, computers, audio equipment, microphones, speakers, visual equipment, cameras, some combination thereof, and the like.

The portions of the circulating gas 36A exiting the fan unit 34 may be at a relatively high pressure as compared to the portions of the circulating gas 36B and 36C entering the heat exchanger 32. A relatively high-pressure area 40 may be defined beyond the fan unit 34. Circulating gas 36A entering this high-pressure area 40 may be attracted to a relatively low-pressure area 38 defined by the storage area 35. A portion of the relatively high-pressure circulating gas 36B and 36C may flow towards the storage area 35 and form a loopback flow 36G. The loopback flow 36G may enter the storage area 35 and circulate around the equipment storage devices 37. In exemplary embodiments, the loopback flow 36G may additionally or alternatively circulate through some or all of the equipment storage devices 37. One or more fans 41 may be located within or near the storage areas 35 in order to force movement of the loopback flow 36G around or through the equipment storage devices 37 and around or through the equipment located thereon. The fans 41 may be controlled, at least in part, by data received from the sensors 21. In exemplary embodiments, one or more additional barriers 29 may extend between the fan unit 34 and the equipment storage devices 37. The additional barrier(s) 29 may separate the loopback flow 36G initially looping back from the high-pressure area 40 and entering the storage area 35 from the loopback flow 36G exiting the storage area 35 to return to the low-pressure area 38 and the fan unit 34.

The use of the loopback flow 36G, for example, without limitation, may permit only the necessary amount of circulating gas 36G to enter and cool the equipment in the equipment storage devices 37. A significant portion of the circulating gas 36 may remain dedicated to removing heat generated by solar loading at the front channels 42 and 44. Additionally, the use of the loopback flow 36G may permit cooled circulating gas 36G which has already passed through the heat exchanger 31 to be used to cool the equipment in the equipment storage devices 37. Otherwise, the air entering from circulating gas flows 36B and 36C would be relatively warm after just passing through the front channels 42 and 44, respectively. This may permit flexibility in placement, size, shape, and the like of the storage area 35 and the equipment storage devices 37. The size and location of the barriers 39 and 29 as well as the storage area 35 and the equipment storage devices 37 may be selected to control the amount and speed of the loopback flow 36G to match thermal management needs.

The first and second open loop channels 22 and 24 as well as the layers 32 of the heat exchanger 31 may form an open loop pathway for the ambient air 30. The layers 33 of the heat exchanger 31, the low-pressure area 38, the storage area 35, the high-pressure area 40, the first and second front channels 42 and 44, as well as the backlight cavities of the first and second electronic display 18 and 20 may form one or more closed loop pathways for the circulating gas 36. The closed loop pathways may be substantially sealed such that the circulating gas 36 located within may remain substantially free of contaminants or other particulate which may otherwise be present in the ambient air 30. Sensitive electronic equipment may be located along the closed loop pathway(s) and thereby kept substantially free of contaminants or other particulate that may be present in the ambient air 30. Additionally, in this way the sensitive electronic equipment may only be exposed to the circulating gas 36, which may have controlled airspeed, pressure, humidity, and the like. The circulating gas 36 may be cooled by thermal interaction with the ambient air 30 at the heat exchanger 31. Additional cooling may be provided by the various open loop pathways, such as, but not limited to, the open loop channels 22 and 24. The open loop channels 22 and 24 may be placed immediately behind the backlights for the electronic displays 18 and 20, in exemplary embodiments, so as to remove heat generated from the backlights.

In exemplary embodiments, the first transparent cover 14, the first electronic display 18, and the first open loop channel 22 may be part of a first side assembly. Similarly, the second transparent cover 16, the second electronic display 20, and the second open loop channel 24 may be part of a second side assembly. Any number of side assemblies for any number of transparent covers 14 and 16, electronic display 18 and 20, and open loop channels 22 and 24 may be utilized. The side assemblies may be mounted to the housing 12 in a hinged fashion by way of one or more hinges 19 such that the side assemblies may be rotated outwards to access the equipment storage devices 37 and the equipment installed thereon.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention. It is the intention, therefore, to limit the invention only as indicated by the scope of the claims.

Certain operations described herein may be performed by one or more electronic devices. Each electronic device may comprise one or more processors, electronic storage devices, executable software instructions, and the like configured to perform the operations described herein. The electronic devices may be general purpose computers or specialized computing devices. The electronic devices may be personal computers, smartphone, tablets, databases, servers, or the like. The electronic connections and transmissions described herein may be accomplished by wired or wireless means.

What is claimed is:

1. A display assembly with cooling pathways, said display assembly comprising:
an electronic display;
a housing for said electronic display;
a closed, continuous airflow pathway extending within the housing;
one or more partitions located within the housing and partially separating an equipment storage area for electronic equipment from the continuous airflow pathway, said one or more partitions defining, at least in part, a sub-pathway within, but separated from, the continuous airflow pathway; and
one or more fans, which when activated, cause a portion of a flow of circulating gas traveling through the closed, continuous airflow pathway to leave the closed, continuous airflow pathway while a remainder of the flow continues through the closed, continuous airflow pathway and instead travel through the sub-pathway pathway before rejoining the closed, continuous airflow pathway.

2. The display assembly of claim 1 wherein:
the closed, continuous airflow pathway extends forward and rearward of the electronic display.

3. The display assembly of claim 2 wherein:
the closed, continuous airflow pathway forms a loop about the electronic display.

4. The display assembly of claim 2 wherein:
a cover panel forming part of the housing and located forward of, and spaced apart from, a forward surface of the electronic display; and
a portion of the closed, continuous airflow pathway extends between an interior surface of the cover and the forward surface of the electronic display.

5. The display assembly of claim 3 wherein:
the one or more fans comprise a first set of one or more fans;
the first set of one or more fans is located within, at an entrance to, or at an exit of, the equipment storage area; and
the first set of one or more fans, when activated, moves the portion of the flow of the circulating gas through at least part of the sub-pathway.

6. The display assembly of claim 5 wherein:
the one or more fans comprise a second set of one or more fans;
the second set of one or more fans is located along the closed, continuous airflow pathway and outside of the equipment storage area; and
the second fan, when activated, moves the remainder of the flow of the circulating gas through at least part of a remainder of the closed, continuous airflow pathway.

7. The display assembly of claim 6 wherein:
the second set of one or more fans, when activated, causes the remainder of the flow of the circulating gas within the remainder of the closed, continuous airflow pathway to be at a first volumetric flow rate; and
the first set of one or more fans, when activated, causes the portion of the flow of the circulating gas within the sub-pathway to be at a second volumetric flow rate which is less than the first volumetric flow rate.

8. The display assembly of claim 7 wherein:
the first fan is located rearward of the electronic display; and
the second fan is located rearward of the electronic display.

9. The display assembly of claim 8 further comprising:
a heat exchanger located along the closed, continuous airflow pathway and rearward of the electronic display, wherein the second fan is located adjacent to the heat exchanger.

10. The display assembly of claim 9 wherein:
the heat exchanger comprises a first set of multiple ducted airflow pathways forming part of the closed, continuous airflow pathway and a second set of multiple ducted airflow pathways fluidly connected to an ambient environment; and
the first set of multiple ducted airflow pathways alternates with the second set of multiple ducted airflow pathways.

11. The display assembly of claim 6 wherein:
the second set of one or more fans, when activated, causes the flow of the circulating gas within a portion of the remainder of the closed, continuous airflow pathway located rearward of the electronic display to travel, at least primarily, in a first direction; and
the first set of one or more fans, when activated, causes at least some of the portion of flow of the circulating gas within the sub-pathway to travel, at least primarily, in a second direction.

12. The display assembly of claim 11 wherein:
the first direction opposes the second direction.

13. The display assembly of claim 6 wherein:
the sub-pathway pathway is fluidly connected to a portion of the closed, continuous airflow pathway located rearward of the electronic display in at least two different locations; and
an entrance to the sub-pathway is located at a first side of the second fan and an exit to the sub-pathway is located fluidly at a second side of the second fan.

14. The display assembly of claim 6 further comprising:
a second electronic display located within the housing; and
a second cover panel forming part of the housing and located forward of, and spaced apart from, a forward surface of the second electronic display, wherein:
the closed, continuous airflow pathway extends forward and rearward of the second electronic display;
a portion of the closed, continuous airflow pathway extends between both the first and second electronic displays;
the fan is located between the first and second electronic displays;
the equipment storage area is located between the first and second electronic displays; and
the second fan is located between the first and second electronic displays.

15. The display assembly of claim 1 wherein:
the sub-pathway extends about at least three sides of the equipment storage area.

16. The display assembly of claim 1 further comprising:
electronics for operating the display assembly, including the electronic display and the fan, located within the equipment storage area.

17. The display assembly of claim 16 further comprising:
an electronic storage device located within the equipment storage area for at least some of the electronics.

18. The display assembly of claim 1 wherein:
the electronic display comprises a liquid crystal display with direct backlighting.

19. A display assembly with cooling pathways, said display assembly comprising:
an electronic display for displaying images comprising a liquid crystal display with direct backlighting;
a housing for said electronic display;
a cover panel forming part of the housing and located forward of, and spaced apart from, a forward surface of the electronic display, said cover panel being translucent or transparent such that the images displayed at the electronic display are visible through the cover panel;
a closed, continuous airflow pathway extending within the housing such that a first portion of the closed, continuous airflow pathway extends between an interior surface of the cover and the forward surface of the electronic display and a second portion of the closed, continuous airflow pathway extends rearward of the electronic display;
one or more partitions located within the housing and partially separating an equipment storage area for electronic equipment from the continuous airflow pathway, said one or more partitions defining a sub-pathway forming part of the closed, continuous airflow pathway, wherein said equipment storage area and said sub-pathway are located, in their entireties, rearward of the electronic display;
one or more fans comprising:
a first set of one or more fans, located within, at an entrance to, or at an exit of, the equipment storage area, which when activated, causes a portion of a flow of circulating gas traveling through the second portion of the closed, continuous airflow pathway to leave the closed, continuous airflow pathway and instead travel through the sub-pathway before rejoining the closed, continuous airflow pathway; and
a second set of one or more fans located along the second portion of the closed, continuous airflow pathway and outside of the equipment storage area, which when activated, causes the flow of the circulating gas traveling through the closed, continuous airflow pathway;
a heat exchanger located along the closed, continuous airflow pathway and rearward of the electronic display, said heat exchanger comprising a first set of multiple ducted airflow pathways forming part of the closed, continuous airflow pathway and a second set of multiple ducted airflow pathways fluidly connected to an ambient environment, where said the first set of multiple ducted airflow pathways alternates with the second set of multiple ducted airflow pathways; and
electronics for operating the display assembly, including the electronic display, the fan, and the second fan, located within the equipment storage area.

20. A display assembly with cooling pathways, said display assembly comprising:
an electronic display for displaying images comprising a liquid crystal display with direct backlighting;
a housing for said electronic display;
a cover panel forming part of the housing and located forward of, and spaced apart from, a forward surface of the electronic display, said cover panel being translucent or transparent such that the images displayed at the electronic display are visible through the cover panel;
a closed, continuous airflow pathway extending within the housing such that a first portion of the closed, continuous airflow pathway extends between an interior surface of the cover and the forward surface of the electronic display and a second portion of the closed, continuous airflow pathway extends rearward of the electronic display;
one or more partitions located within the housing and separating an equipment storage area for electronic equipment from the continuous airflow pathway, said one or more partitions defining a sub-pathway forming part of the closed, continuous airflow pathway, wherein said equipment storage area is located rearward of the electronic display;
a first set of one or more fans, located within, at an entrance to, or at an exit of, the equipment storage area which when activated, causes a portion of a flow of circulating gas traveling through the second portion of the closed, continuous airflow pathway to leave the closed, continuous airflow pathway and instead travel through the sub-pathway at a first volumetric flow rate before rejoining the closed, continuous airflow pathway;
a second set of one or more fans located along the second portion of the closed, continuous airflow pathway and outside of the equipment storage area, which when activated, causes the flow of the circulating gas traveling through the closed, continuous airflow pathway at a second volumetric flow rate which is greater than the first volumetric flow rate;
a heat exchanger located along the closed, continuous airflow pathway and rearward of the electronic display, said heat exchanger comprising a first set of multiple ducted airflow pathways forming part of the closed, continuous airflow pathway and a second set of multiple ducted airflow pathways fluidly connected to an ambient environment, where said the first set of multiple ducted airflow pathways alternates with the second set of multiple ducted airflow pathways; and
electronics for operating the display assembly, including the electronic display, the fan, and the second fan, located within the equipment storage area.
